(19) United States
(12) Patent Application Publication
(10) Pub. No.: US 2002/0185294 A1
(43) Pub. Date: Dec. 12, 2002

(54) Push-fit shield and method for fabricating same

(76) Inventors: Anatoliy Shlyakhtichman, Buffalo Grove, IL (US); Vladislav Pirkhalo, Wheeling, IL (US); Igor Vinokur, Skokie, IL (US); Igor Shkarovsky, Buffalo Grove, IL (US)

Correspondence Address: Michael J. Turgeon, Esq., Vedder, Price, Kaufman & Kammholz, 222 North LaSalle Street, Suite 2400, Chicago, IL, 60601, US

(21) Appl. No.: 09/844,068

(22) Filed: Apr. 27, 2001

(51) Int. Cl. H05K 9/00

(52) U.S. Cl. 174/52.1

(57) ABSTRACT

An EMI/RFI shield comprises a frame and a push-fit lid. The frame includes a frame top wall having outer frame edges jointly defining a frame perimeter of predetermined configuration in plan view, and a plurality of side walls depending from the frame edges. The lid includes a frame cover wall having free edges jointly defining a cover wall perimeter complementary in configuration in plan view to that of the frame perimeter, and a plurality of elongated spring fingers formed integrally of the cover wall and extending from the free edges. The fingers are configured to extend laterally beyond said frame perimeter and then downwardly and inwardly to engage the side walls when the lid is fit on the frame. At least some of the fingers have contact portions that are received in slots provided in the frame side walls.

The present invention relates to surface mountable EMI/RFI shields and, more particularly, to two-piece shields of the type having removable push-fit or snap-fit lids.

### BACKGROUND OF THE INVENTION

Modern electronic equipment includes electrical components and circuits mounted on a substrate that are sensitive to electromagnetic interference (EMI) and radio frequency interference (RFI). Such EMI/RFI interference may originate from internal sources within the electronic equipment or from external EMI/RFI interference sources. Interference can cause degradation or complete loss of important signals, rendering the electronic equipment inefficient or inoperable. Accordingly, the circuits (sometimes referred to as RF modules or transceiver circuits) require EMI/RFI shielding in order to function properly. The shielding reduces interference not only from external sources, but also from various functional blocks within the RF module. One type of prior art surface mountable shield is a five-sided metal enclosure, known as a can, that is mounted by automated equipment on the PCB (printed circuit board) and fits over the shielded components. The can is soldered to the board at the same time as are the electronic components. However, repairing components and fixing other problems covered by a soldered can shield is impossible without removing the shield. Removing a soldered shield is an expensive and time consuming task that can cause additional damage to the assembly and/or possibly remove the cause of the original fault leading to no-trouble-found defects. The access problem with soldered can shields can be avoided by using shields that can be opened when repair work is necessary.

Such openable shields are known and in the past have included cut-to-open shields (such as shown in patent Nos. 5,354,951; 5,614,694 and 5,365,410), and shields with snap-on or push-fit removable lids (such as shown in patent Nos. 5,895,884; 5,844,784; and 5,495,399). The two-piece shields comprise a frame or base member and a lid that is intended to provide secure mechanical locking and excellent electrical connection to the frame. Heretofore, mechanical locking of lid and frame has been accomplished by use of dimples and receiving slots provided on the frame and lid sidewalls (e.g. U.S. Pat. No. 5,895,884), or oppositely flared interlocking fingers (e.g. U.S. Pat. No. 5,354,951). It is desirable that the frame of a two-piece shield be surface mountable by automated equipment both with the lid affixed and, alternatively, without the lid affixed. Such requirement necessitates that the frame have a surface near its center of gravity so it can be handled by vacuum robotic pick and place equipment with the cover removed. U.S. Pat. No. 5,495,399 discloses an example of such a frame.

With surface mount technology, shields are attached, typically, via soldering to grounded traces positioned both on the PCB substrate and around the electrical circuits generating (or requiring protection from) the interference as well as around the electrical circuits that are susceptible to interference. Oftentimes, the shields must be attached in close adjacency. The traces (which are typically comprised of gold-plated copper trace) are fabricated using known bonding and plating techniques during construction of the substrate, which typically comprises printed circuit board material, such as polyamide or epoxy-based flame retardant industrial fiberglass (G10-FR4). Generally, the traces are segmented, but in some applications continuous traces are employed. The plurality of traces are electrically coupled to a ground plane. The traces are generally no less than 1.00 millimeter wide (or 3½ times the shield wall material thickness) so as to ensure an effective metallurgical connection between the plurality of the contact points of shields and the plurality of traces. Traces for adjacent shields are separated from one another by at least 0.26 millimeter of solder mask barrier or bare substrate material for simple can shields. For removable cover shields the tracings must be separated by at least 1.0 millimeter to accommodate shield cover wall material thicknesses and assembly tolerances.

Initially, the substrate is subjected to a screening process that deposits a predetermined amount of solder paste on the plurality of traces. To ensure secure attachment, the amount of solder (and the size of the plurality of traces) should be sufficient to allow solder to “wick” or adhere on both sides of each of the plurality of contacts of shields during reflow. The shield assembly is reflow heated up to a temperature that is sufficient to melt the solder paste to a liquidus state. The liquidus solder wicks up on both sides of the shield wall and forms an effective metallurgical interconnection therebetween.

Shields are generally fabricated, using known progressive metal stamping, forming or slide tool techniques, from 0.05 millimeters to a 0.30 millimeters thick sheet stock of a nickel-silver alloy, a tin-plated steel, or other suitable electrically conductive material. The side portions of prior art shields are then folded along fold lines into position based on the maximum height of the portion of the transceiver circuit that is to be shielded. Depending on the type of components comprising this portion of the transceiver circuit, the available height for the shields might be less than 2.0 millimeters. However, two-piece shields with push fit lids having side walls of the general type shown in U.S. Pat. No. 5,895,884; 5,844,784; and 5,495,399 have required a minimum vertical space of about 2.25 millimeters because there must be a spacing of a minimum of 0.5 millimeters between the PCB and the bottom edge of each lid side wall to prevent the lid from being soldered during reflow heating.

Shields typically include a plurality of holes or apertures to facilitate reflow heating interiorly of the shield, to enable cooling of the covered circuit elements during use, and to permit visual inspection of the portions of the transceiver circuit there beneath. Such holes are generally sufficiently small (one-eighth wavelength or less at the highest frequency for which shielding is necessary) to prevent passage of interfering EFI or RFI. The size of the holes of shields can be varied based on the sensitivity of the portion of the transceiver circuit there beneath. For more sensitive circuitry, the diameter of the holes are made smaller. Distal separations between the plurality of contacts and openings between the bottom edge periphery of shields and the skipped ones of the plurality of traces are similarly constrained.

In the known construction of two-piece shields there can be a poor contact between the shield lid and the shield frame due to tolerance build up (tolerance stacking). Then, at high frequencies the lid or a part of it will rise to an impedance and begin to radiate or to receive radiation. The protective effect of the EMC enclosure or a part of it is then lost.

Two-piece openable shields of known construction also suffer the drawback of requiring usage of a new lid each time the lid is removed due to actual (or perceived possible) deformation of the removed lid occasioned during the removal process. Such deformation has come to be expected by reason of excessive deflection of the lid sides during removal and/or by reason of line workers using improper techniques of lid removal to save time (e.g. using the worker's thumbnail to pry off the lid). Additionally, designs relying on interlocking fingers or dimples have posed design and production difficulties. In particular, it is difficult to hold tolerances and, consequently, the locking capabilities and forces.

Typically, shields are made from sheet metal approximately 0.20 millimeters in thickness. Tin plated CRS is a common material. Shields for cellular phones are typically applied to circuit boards using surface mount processes (e.g. vacuum pick and place) and must meet rigid quality control standards. They also must be produced in large quantity at very low cost.

### SUMMARY OF THE INVENTION

The present invention concerns an RFI shield assembly having a removable lid that can easily be opened and closed to permit repairs to underlying shielded components. The lid is reusable as it is not deformed during removal due to the fact that it is not easily susceptible to improper removal techniques. The shield assembly may be used anywhere that a shield must cover a group of components that might be considered a potential source of manufacturing defects. The invention may be used on any electrical device that requires RFI/EMI shielding whether to shield incoming or outgoing emissions. Examples include computers, cellular telephones, pagers, modems, radios and the like.

It is one object of the present invention to provide a two-piece shield requiring simplified fabrication processes.

A related object is to provide such a shield having reduced susceptibility to adverse tolerance stacking.

Another object is to provide a two-piece shield having improved mechanical and electrical lid and frame connectivity.

A still further object is to provide a shield with reduced material content and consequent reduction in weight.

Another object of the invention is to provide a two-piece shield having improved lid removal functionality.

These and other objects are realized, we have discovered, through elimination of lid side walls and by provision of easily formed spring fingers or tabs which engage the frame sidewalls. The tabs have projections extending outwardly of the frame sidewalls to enable the tabs to be easily grasped by line workers and deflected outwardly in a direction away from the frame sidewalls to facilitate removal of the lid. The tabs also include a generally “C” shaped bend portion forming opposed concave and convex tab surfaces with the convex surface facing the frame sidewalls. The frame sidewalls have slots for snap-fit receipt of the convex surface side of some of the tabs.

Other features and advantages of the invention will become apparent from the drawings and detailed description to follow.

### BRIEF DESCRIPTION OF THE DRAWINGS

In the drawings wherein like numerals identify like parts throughout:

FIG. 1 is an expanded perspective view of a shield assembly incorporating the principles of the present invention;

FIG. 2 is a top plan view of the frame preform;

FIG. 3 is a top plan view of the lid preform;

FIG. 4 is a top plan view of the frames;

FIG. 5 is a front elevational view of the frame of FIGS. 1 and 4;

FIG. 6 is a front elevational view of the lid of FIG. 1;

FIG. 7 is a top plan view of the shield assembly of FIG. 1;

FIG. 8 is an enlarged view of a lid spring finger;

FIG. 9 is a sectional view taken, as indicated, along the line 9-9 of FIG. 7;

FIG. 10 is a sectional view taken, as indicated, along the line 10-10 of FIG. 7;

FIG. 11 is an enlarged framentary top plan view of adjacent shields of FIGS. 1-10 in staggered relationship on a PCB; and

FIG. 12 is a fragmentary top plan view of an alternate embodiment.

### DETAILED DESCRIPTION

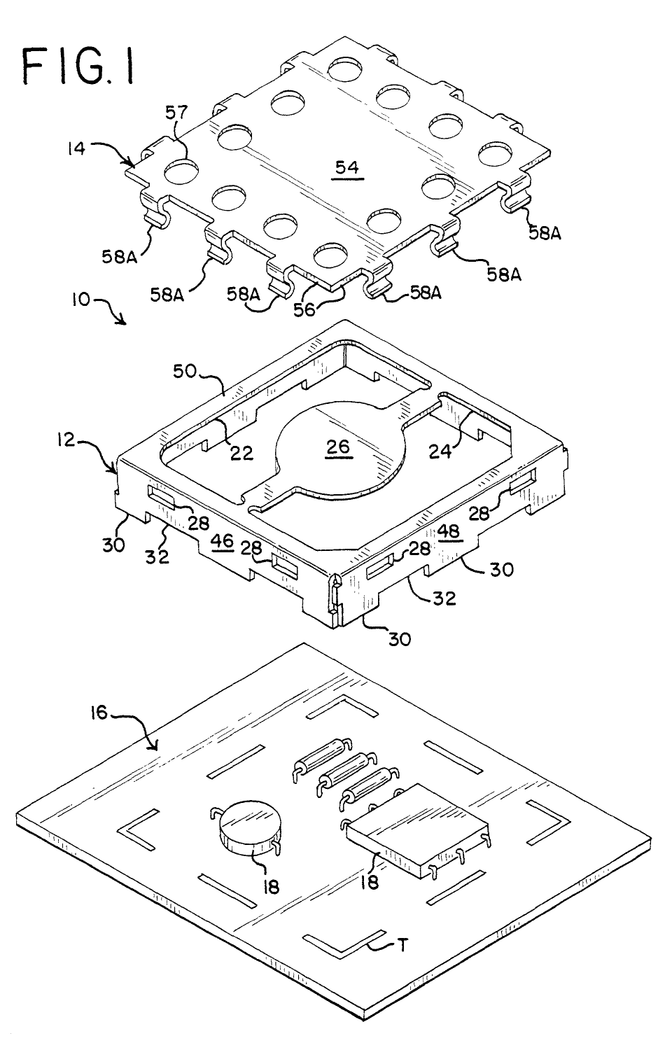

With reference to the drawings a surface mount shield assembly 10 incorporating the principles of the present invention is shown in FIG. 1 to comprise a frame 12 and lid 14. A circuit board (PCB) 16 has circuit elements 18 disposed thereon surrounded by traces T onto which the frame 12 is placed, typically, by vacuum pick and place equipment (not shown).

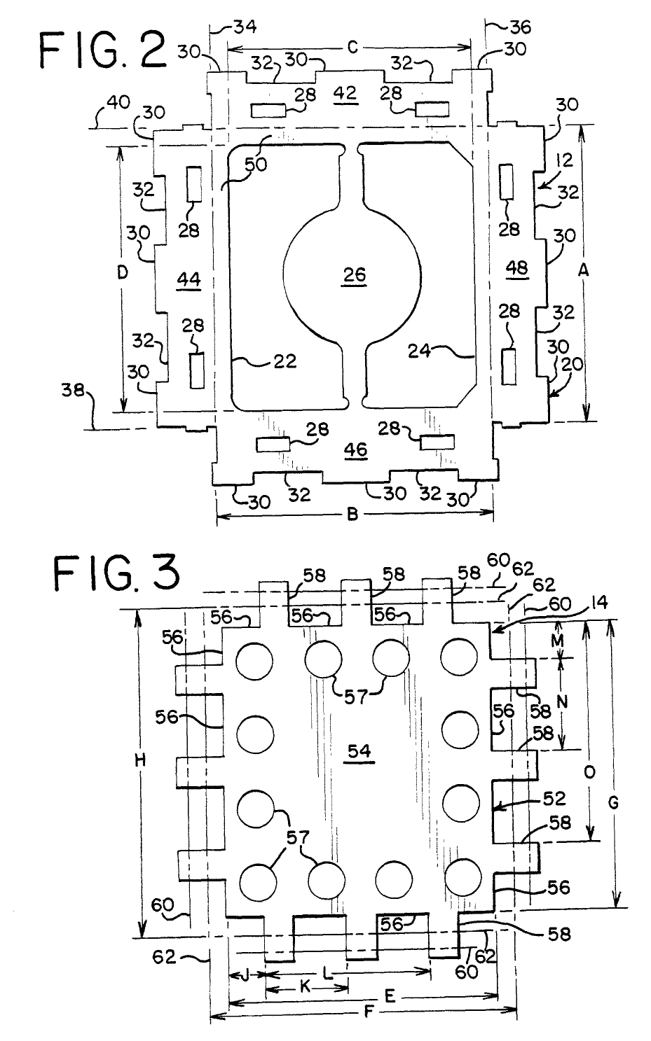

FIG. 2 shows a frame preform 20 comprising a flat sheet of metal stock that has been produced in conventional fashion such as by blanking or chemical milling. Preform 20 has interior, relatively large cut-out portions 22 and 24 defining therebetween a frame pick up area 26 located at the center of gravity of the frame 12, and a plurality of relatively small apertures 28 spaced from cut out portions 22 and 24. The free edge perimeter of the preform 20 is formed to define a series of frame contacts 30 separated by indented portions 32. The preform 20 is then folded along fold lines 34, 36, 38 and 40 in conventional fashion to form frame side walls 42, 44, 46 and 48 and a band shaped frame top wall 50 extending continuously about the outer perimeter of the frame 12. As shown, each of the side walls 42, 44, 46 and 48 integrally merges with the top wall 50 at a corner formed via the folding operation, whereby the corners thus formed define outer frame edges of the top wall 50 jointly defining a frame perimeter of predetermined configuration in plan view (rectangular in the illustrated embodiment).

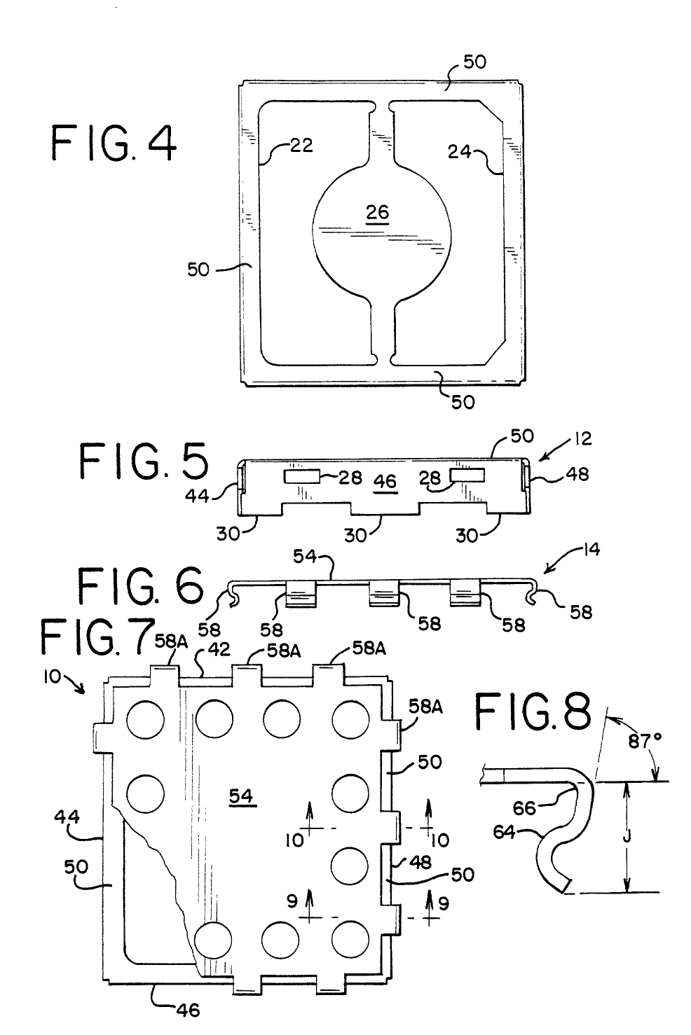

FIG. 3 shows a lid preform 52 comprising a flat sheet of metal stock that has been produced in conventional fashion. Preform 52 includes a frame cover wall portion 54 having peripheral free edge portions 56 separated by a plurality of elongated finger-like extensions or tabs 58 extending outwardly from the free edge portions 56. A plurality of apertures 57 are cut out from the frame cover 54. Fingers 58 of the lid preform 52 are then folded along fold lines 60 and 62 to form deflectable spring fingers 58A. It will be noted that the free edges 56 of the frame cover wall 54 jointly define a cover wall perimeter that is complimentary in configuration in plan view to the frame perimeter but is not necessarily fully coextensive therewith. That is, in the presently preferred embodiment illustrated in FIGS. 1 to 10, frame dimension A is greater than lid dimension G (see FIGS. 2 and 3) and frame dimension B is greater than lid dimension E. When the lid 14 is fitted onto the frame 12, the free edges 56 of the cover wall 54 do overlay portions of the frame top wall 50. That is, lid dimension E is greater than frame dimension C (see FIGS. 2 and 3) and lid dimension G is greater than frame dimension D. Thus, in the embodiment of FIGS. 1 to 10 surface portions of the cover wall 54 immediately bordering its free edges 56 are disposed in surface-to-surface contact with frame top wall 50 along a continuous contact zone bordering, but spaced slightly from, the frame edges when the lid 14 is fit onto the frame 12 as best shown in FIG. 7.

With further reference to FIGS. 2 and 3 the lid dimension H separating parallel fold lines 62 (on the opposite sides of the lid preform 52) is greater than frame dimension A, and the lid dimension F separating parallel lid fold lines 62 is greater than frame dimension B so that finger extensions 58 extend beyond the frame edge perimeter when the lid 14 is fit onto the frame 12 (see FIGS. 8 and 9). As best shown in FIG. 8, when finger extensions 58 are formed (i.e. folded) to form spring fingers 58A, each spring finger 58A has a contact bend region defining a convex shaped surface 64 and a primary bend region 66 located intermediately along its length between one of the cover wall edges 56 and the contact bend region 64. Thus, primary bend region 66 is located beyond the frame edge perimeter then the lid 14 is fit onto the frame 12. In the preferred form illustrated in FIGS. 1-10 at the primary bend region 66 the finger extensions 58 are bent through an angle greater than 90° (that is, 93°) and the contact bend region 64 has a generally “C” shaped configuration in cross section. Apertures 28 of the frame side walls 42, 44, 46 and 48 are aligned with and located a distance below the frame top wall 50 to be engaged by the convex contact portion of spring fingers 58A in a snap-fit relation. It will be noted that less than all of the spring fingers 58A are aligned with receiving apertures 28, those fingers 58A which are not aligned with an aperture 28 having their contact region 64 bearing against a side wall of the frame in pressed engagement due to deflection of the spring fingers 58A.

The mechanical interlock between spring fingers 58A and apertures 28 is sufficient to permit above-described two-piece surface mount shield to be placed on the PCB traces T with the lid 14 fit onto the frame 12. Alternatively, as is evident, the frame 12 can be placed onto the traces T without the lid 14 being affixed.

It can be appreciated that the lid 14 of the present invention eliminates tolerance stacking problems in each of the X-Y-Z coordinates due to absence of lid sidewalls and elimination of the traditional use of the dimple/recess interlock heretofore employed. The combination in the lid 14 of (i) a sideless cover 54 with finger extensions 58 each projecting beyond the frame perimeter (and frame side walls) prior to the primary bend region 66, coupled with (ii) a contact portion 64 that is deflectable due to the spring action of the spring fingers 58A, absorbs any tolerance buildup. The apertures 28 are wider than the spring fingers 58A and engage a convex surface 66 thereof so that tolerance problems of the aperture-spring finger relationship are eliminated. Further, it can be appreciated that the lid is extremely easy to fabricate.

Each corner C1, C2, C3 and C4 of the lid preform (FIG. 3) is a convex “free corner.” That is, there is absence of material to be formed by folding at the preform locations that define the lid corners in plan view. As will be appreciated by those skilled in fabrication, the free corner preform configuration eliminates the need for dedicated tooling for each size of lid. In turn this produces efficiencies and cost reductions in fabrication of the lid 14. By way of further explanation, note that the frame preform of FIG. 2 lacks free corners. Thus, for example, after walls 44 and 48 are formed by folding the preform along fold lines 34 and 36, the tools required for forming walls 42 and 46 by folding along fold lines 38 and 40 are of necessity restricted in length to dimension B so they fit between walls 42 and 46. Such tools are of no use for larger or smaller sized lids.

It will be appreciated that the specific lid preform embodiment of FIG. 3 is of double free corner configuration in that corners C1, C2, C3 and C4 have two free corner side edges even in the preform condition of FIG. 3.

The frame 12 of the embodiment illustrated in FIGS. 1 through 10 has been made using 0.20 millimeter tin plated CRS with the dimensions hereafter set forth. The height of each of the side walls 42, 44, 46 and 48 measured from the bottom edge of the contacts 30 to the upper surface of top wall 50 is 2.54 millimeters. Frame dimension A is 13.66 millimeters. Frame dimension B is 12.7 millimeters. Frame dimension C is 10.7 millimeters. Frame dimension D is 11.66 millimeters.

Each aperture 28 is 0.60 millimeter×1.5 millimeters and is disposed 0.50 millimeters below the top surface of frame top wall 50.

The lid 14 of FIGS. 1 through 10 is formed of 0.13 millimeter thick tin plated CRS. Lid dimensions E and G are 11.76 millimeters and 12.72 millimeters, respectively. Each elongated finger extension 58 in flat preform configuration has a length of 2.0 millimeters and a width of 1.3 millimeters. The primary bend region 66 has a bend radius R1 of 0.13 millimeter while contact portion 64 has a bend radius R2 of 0.17 millimeters. The spring fingers 58A have a dimension SH of 1.17 millimeters and a first bend angle of 87° (see FIG. 8). The bend angle of the primary bend 66 coupled with the “C” shaped bend of the contact bend region 64 spaces the contact regions of opposing spring fingers a distance apart a distance that is 0.18 millimeters less than frame dimensions A and B. Spring finger separation dimensions are as follows:

| Dimension | Millimeters |
|---|---|
| J | 1.6 |
| K | 3.6 |
| L | 7.2 |
| M | 1.6 |
| N | 4.08 |
| O | 8.16 |

Although the spring fingers 58A project beyond the frame periphery, it will be noted that shields can be placed in close adjacency on a PCB. In the embodiment of FIGS. 1-10, the spring fingers 58A project 0.455 millimeter beyond the periphery of the frame 12. Shields which are to be located adjacent each other can easily be designed so that their respective spring fingers are staggered as illustrated in FIG. 11.

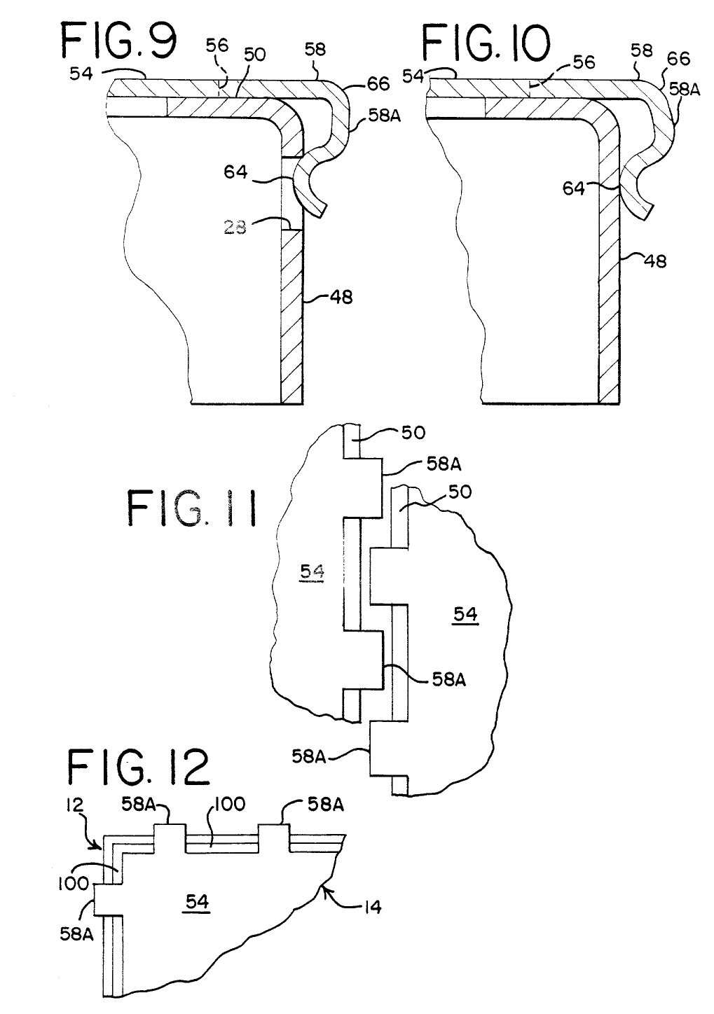

It will be apparent that the lid 14 of the present invention can be used with frames that lack a band shaped top wall, like top wall 50, and that certain applications may not require (or permit) surface-to-surface contact between the lid cover wall and the frame. Thus, for example, a gap 100 may exist between the free edges 56 of cover wall 54 of lid 14 and wall portions of the frame 12 as illustrated in FIG. 12 provided that the gap is sufficiently small to attenuate EMI ingress/egress.

It will be appreciated that the lid-to-frame locking capability can be controlled by variation of the spring finger width, height J, bend radii of finger bend region 66 and contact portion 64, the thickness of the sheet metal, and the number of spring finger employed. Typical two-piece shield specifications call for a lid-two-frame locking force of about 35±15 newtons which is satisfied by the illustrated embodiment.

It should be further understood by those with ordinary skill in the art that the foregoing presently preferred embodiments are exemplary only and that the intended description thereof is likewise by way of words of example rather than words of limitation, and their use does not preclude inclusion such modifications, variations and/or additions to the present invention as would be readily apparent to one of ordinary skill in the art, the scope of the present invention being set forth in the appended claims.

What is claimed is:

1. An EMI/RFI shield comprising a frame and a push-fit lid, said frame including a frame top wall having outer frame edges jointly defining a frame perimeter of predetermined configuration in plan view, and a plurality of side walls depending from said frame edges, said lid including a frame cover wall having free edges jointly defining a cover wall perimeter complementary in configuration in plan view to that of the frame perimeter, and a plurality of elongated spring fingers formed integrally of said cover wall and extending from said free edges, said fingers being configured to extend beyond said frame perimeter engage said side walls when said lid is fit on said frame

2. A shield in accordance with claim 1 wherein surface portions of said cover wall immediately bordering the free edges thereof are disposed in surface-to-surface contact with said frame top wall along a continuous contact zone adjacent said frame edges when said lid is fit on said frame.

3. A shield in accordance with claim 2 wherein said contact zone has a width of at least 0.5 millimeter.

4. A shield in accordance with claim 2 wherein said frame top wall includes a band shaped wall portion extending continuously about the frame periphery.

5. A shield in accordance with claim 2 wherein said frame top wall includes at least one aperture spaced from said frame edges, said contact zone being located between said aperture and said frame edges.

6. A shield in accordance with claim 1 wherein said frame is formed of metal stock having a thickness greater than that of the metal stock of the lid.

7. A shield in accordance with claim 2 wherein said contact zone is spaced from said frame edges.

8. A shield in accordance with claim 1 wherein said contact zone entirely resides in a common plane.

9. A shield in accordance with claim 1 wherein each of said fingers includes a contact bend region defining a convex shaped surface for contact with one of said side walls when said lid is fit on said frame.

10. A shield in accordance with claim 9 wherein each of said fingers includes a primary bend region located intermediately along its length between said cover wall and said contact bend region.

11. A shield in accordance with claim 9 wherein said side walls include a plurality of apertures, the convex shaped surface of each of a plurality of said spring fingers being matingly engageable with corresponding ones of said apertures when said lid is fit on said frame.

12. A shield in accordance with claim 11 wherein the contact bend regions are formed at the free ends of the spring fingers.

13. An EMI/RFI shield comprising a frame and a press fit lid, said lid being formed from metal stock of a thickness of about 0.1 to 0.5 millimeters,
said frame including a frame top wall having outer frame edges jointly defining a frame perimeter of predetermined configuration in plan view, and a plurality of side walls depending from said frame edges,
said lid including a frame cover wall having free edges jointly defining a cover wall perimeter complementary in configuration in plan view to that of the frame perimeter, and a plurality of elongated spring fingers formed integrally of said cover wall and extending from said free edges, said fingers being configured to engage said side walls when said lid is seated on said frame, each of said fingers having a uniform width along its length of from about 2.0 millimeters to about 8.0 millimeters.

14. A shield in accordance with claim 13 wherein each of said fingers includes a contact bend region formed proximal the free and thereof defining a convex shaped surface having a radius of about 0.37 millimeters.

15. A shield in accordance with claim 13 wherein each of said side walls includes an elongated aperture for mating receipt of said convex shaped surface and having a width 0.2 millimeter greater than the width of the corresponding of said fingers, and a height of about 0.6 millimeter.

16. A surface mountable shield assembly comprising a frame having a plurality of side walls, said side walls having upper portions jointly defining a frame perimeter of predetermined configuration in plan view, and a lid for the frame, said lid including a frame cover wall having free edges jointly defining a cover wall perimeter complimentary in configuration in plan view to the frame perimeter, and a plurality of spring fingers extending from said free edges, each of said fingers having a frame contact portion and a bend portion, said bend portion being located intermediately between said contact portion and one of said free edges, said bend portion being disposed beyond the frame perimeter with said contact portion being in pressed engagement with one of said side walls when the lid is fit on the frame.
